(19) United States
(12) Patent Application Publication
(10) Pub. No.: US 2012/0098599 A1
(43) Pub. Date: Apr. 26, 2012

(54) ENHANCEMENT MODE HEMT FOR DIGITAL AND ANALOG APPLICATIONS

(75) Inventors: Chih-Yang Chang, Gainesville, FL (US); Fan Ren, Gainesville, FL (US); Stephen John Pearton, Gainesville, FL (US)

(73) Assignee: Univeristy of Florida Research Foundation Inc., Gainesville, FL (US)

(21) Appl. No.: 13/380,956

(22) PCT Filed: Jun. 29, 2010
(86) PCT No.: PCT/US10/40357

§ 371 Date: Dec. 27, 2011

Related U.S. Application Data
(60) Provisional application No. 61/221,966, filed on Jun. 30, 2009.

(51) Int. Cl. H03F 3/21; H01L 21/335; H01L 29/778; H01L 27/088; H01L 29/20; H01L 29/161

(52) U.S. Cl. 330/277; 257/76; 257/77; 257/194; 257/195; 438/172; 257/E27.061; 257/E29.246; 257/E29.089; 257/E29.084; 257/E21.403

(57) ABSTRACT

An enhancement mode (E-mode) HEMT is provided that can be used for analog and digital applications. In a specific embodiment, the HEMT can be an AlN/GaN HEMT. The subject E-mode device can be applied to high power, high voltage, high temperature applications, including but not limited to telecommunications, switches, hybrid electric vehicles, power flow control and remote sensing. According to an embodiment of the present invention, E-mode devices can be fabricated by performing an oxygen plasma treatment with respect to the gate area of the HEMT. The oxygen plasma treatment can be, for example, an O2 plasma treatment. In addition, the threshold voltage of the E-mode HEMT can be controlled by adjusting the oxygen plasma exposure time. By using a masking layer protecting regions for depletion mode (D-mode) devices, D-mode and E-mode devices can be fabricated on a same chip.

### CROSS-REFERENCE TO RELATED APPLICATION

This application claims the benefit of U.S. Provisional Application Ser. No. 61/221,966 filed Jun. 30, 2009, which is hereby incorporated by reference in its entirety, including all figures, tables and drawings.

### BACKGROUND OF INVENTION

In a depletion mode high electron mobility transistor (HEMT), an electric field generated from the gate electrode is used to deplete a two dimensional electron gas channel at the interface of wide and narrow energy bandgap semiconductor, such as AlN/GaN or AlGaN/GaN. A control voltage can be applied to the gate electrode to directly affect and control the amount of current flowing through the channel. The depletion mode transistors function as “normally-on” devices when used as switches. For an enhancement mode transistor, no channel is present and no current flow occurs until the transistor is biased for operation. In particular, the transistor is biased and a voltage is applied to the gate in order to move the two dimensional electron gas channel below the Fermi level. Once another voltage is applied between the source and drain, the electrons in the two dimensional electron gas channel move from source to drain. The enhancement mode transistors are commonly used for digital and analog integrated circuits (ICs) and can function as “normally-off” devices.

Enhancement mode (E-mode) HEMTs are useful for analog circuit applications, such as RF/microwave power amplifiers or switches.

Direct-coupled FET logic (DCFL) by integration of E-mode and depletion-mode (D-mode) HEMTs, referred to as E/D DCFL, is currently being researched for high speed and high-density digital circuit applications.

Wide band gap AlGaN/GaN HEMTs have emerged as devices of interest for RF/microwave power amplifiers because of their high power and high speed handling capabilities. As the push to scale down and increase performance continues for high power, high frequency applications, AlN/GaN HEMTs are emerging as the device structure of choice. In particular, the large band-gap of AlN (6.2 eV) provides improved carrier confinement and lowers gate leakage current as compared to conventional AlGaN barriers and results in improvement of both low and high field carrier transport. Both a high carrier density and high carrier mobility are desirable to achieve high output current.

To reduce alloy scattering and improve channel conductivity, structures with very thin AlN barrier layers are an attractive option for high speed, high voltage, high power devices, if the sheet density under the gate region of the HEMT can be made low enough for E-mode operation.

Current research in AlN/GaN HEMTs shows promise for high power, high temperature applications. In addition, for applications using transistors as switches or high temperature capable integrated circuits, it is also desirable to have normally off or enhancement mode operation devices. Accordingly, there continues to be a need in the art for improved methods and structures for devices capable of performing in high power, high voltage, high speed, and/or high temperature applications.

### BRIEF SUMMARY

Embodiments of the present invention provide devices for digital and analog applications and methods of fabricating the same. According to an embodiment, an E-mode HEMT is provided that can be used for high power digital and analog applications. Embodiments of the present invention can be utilized in power amplifiers and DCFL Circuitry for high speed circuits and switches for hybrid cars. In a specific embodiment, an AlN/GaN HEMT is disclosed that can be fabricated to achieve E-mode operation through an oxygen plasma treatment that oxidizes the AlN surface layer. By controlling the duration of this oxidation treatment, device characteristics can be tuned to achieve both E- and D-mode operation.

For analog RF applications, by using the subject E-mode HEMT, a negative-polarity voltage supply can be eliminated, resulting in reduction to the circuit complexity and cost. For digital applications, the subject E-mode HEMT can be easily utilized in DCFL circuit configurations that feature integration of D-mode and E-mode HEMTs.

AlN/GaN HEMTs fabricated in accordance with embodiments of the present invention can be grown on sapphire or SiC substrates to achieve high power, high temperature applications including, but not limited to applications in telecommunications, hybrid electric vehicles, power flow control and remote sensing. In other embodiments, silicon, silicon or poly silicon carbide (SiC) based silicon on insulator (SOI), or GaN substrates can be used, depending on the application.

### BRIEF DESCRIPTION OF DRAWINGS

FIGS. 1A and 1B show layer structures for an AlN/GaN HEMT in accordance with an embodiment of the present invention.

FIG. 2 shows a cross-sectional view of an E-mode AlN/GaN HEMT according to an embodiment of the present invention.

FIGS. 3A and 3B show DC I_{DS}-V_{DS} characteristics of an AlN/GaN HEMT in accordance with an embodiment of the present invention for D-mode and E-mode comparison. FIG. 3A shows a plot of DC I_{DS}-V_{DS} characteristics with no oxygen plasma exposure (D-mode), and FIG. 3B shows a plot of DC I_{DS}-V_{DS} characteristics where the gate area of the HEMT was exposed to 24 s of oxygen plasma (E-mode).

FIG. 4 shows plots of threshold voltage, drain current at zero gate bias voltage, and maximum drain current, as a function of oxygen plasma exposure time, as well as a single data point of nitrogen plasma exposure for HEMTs fabricated in accordance with embodiments of the present invention.

FIG. 5 shows a plot of the gate current of an AlN/GaN HEMT in accordance with an embodiment of the present invention treated with different oxygen plasma exposure times.

FIGS. 6A and 6B provide comparison plots of 2DEG Hall mobility and sheet resistivity for AlGaN/GaN (circles) and AlN/GaN (diamonds) HEMTs grown on sapphire and SiC by PA-MBE. FIG. 6A shows a plot of 2DEG Hall mobility and FIG. 6B shows a plot of sheet resistivity.

FIG. 7 shows a cross-sectional TEM image of an AlN/GaN HEMT structure fabricated in accordance with an embodiment of the present invention.

FIG. 8 shows an optical microscopy plan view image of an AlN/GaN HEMT structure fabricated in accordance with an embodiment of the present invention.

FIG. 9 shows plots of _{IDS-VDS} characteristics from AlN/GaN HEMTs without any plasma exposure (indicated as lines with boxes) and having 18 s of O₂ plasma exposure (indicated as lines with circles).

FIGS. 10A and 10B show plots of transfer characteristics and breakdown voltage, respectively, for untreated HEMTs (no plasma exposure).

FIGS. 11A and 11B show plots of transfer characteristics and breakdown voltage, respectively, for HEMTs exposed to O₂ plasma for 18 s.

FIGS. 12A and 12B show plots of RF performance of a 24 s O₂ plasma exposed HEMT and dependence of f_{T} and f_{MAX} on O₂ exposure time, respectively.

### DETAILED DISCLOSURE

Embodiments of the present invention provide an enhancement mode (E-mode) HEMT that can be used for analog and digital applications. According to the present invention, E-mode devices can be fabricated by performing a plasma treatment with respect to the gate area of the HEMT. In addition, the threshold voltage of the E-mode HEMT can be controlled by adjusting the plasma exposure time and rf power. Furthermore, the threshold voltage can be positively shifted and current through the gate can be reduced by performing the subject plasma treatment. According to a specific embodiment, the subject plasma treatment is an oxygen plasma treatment. In alternate embodiments, other plasma treatments can be performed to control the threshold voltage of the E-mode HEMT. For example, other plasma treatments, such as N₂O, NO, N₂, He, Ar, Xe, Ne, and NH₃ can be performed in place of, or in addition to, the oxygen plasma treatment.

The subject E-mode device can be applied to high power, high voltage, high temperature applications, including but not limited to telecommunications, hybrid electric vehicles, power flow control and remote sensing.

In a specific embodiment, E-mode AlN/GaN HEMTs are provided. For high temperature applications, the E-mode AlN/GaN HEMT can be grown on, for example, a sapphire, silicon, GaN, SOI, poly SiC, or SiC substrate.

A number of variations on AlN/GaN HEMTs have been explored with notable success. However, AlN can be easily oxidized or etched by some of the chemicals used during device processing. Accordingly, a protective layer deposited on the surface is included to protect the AlN. This protective layer also acts as a gate insulator for the device. Silicon nitride (SiNx) deposited by plasma enhanced vapor deposition or electron beam deposition is one method used to protect the AlN. The typical wet etchants of SiN are hydrofluoric acid (HF) and buffered HF (also referred to as a buffered oxide etch—BOE). When these etchants are used for removing SiN, they attack any exposed AlN. Therefore, after Ohmic contact pattern definition, the SiN cannot be removed by the HF solution or BOB, or the device may become degraded. In addition, CF₄ plasma exposure has shown a passivation effect on the 2DEG of the AlGaN/GaN HEMT. Therefore, CF₄ plasma can also cause problems if used to remove the SiN prior to the Ohmic metal deposition. Accordingly, as one workaround, the Ohmic metal is directly deposited on the protective SiN and the metal is alloyed through the SiN.

Embodiments of the present invention can avoid problems arising from using SiN by omitting SiN as a protective layer and using a different material.

According to an embodiment of the present invention, by using a masking layer protecting regions for D-mode devices, D-mode and E-mode devices can be fabricated on a same chip.

In addition, starting with a D-mode AlN/GaN HEMT, the threshold voltage of the HEMT can be shifted by the exposure of the gate to the subject plasma treatment prior to gate metallization deposition. For example, during an oxygen plasma treatment performed in accordance with an embodiment of the present invention, a portion of the AlN layer is converted into Al oxide. The Al oxide can provide surface protection of the AlN layer for subsequent masking and etching processes, and a high quality gate insulating layer. In addition, the Al oxide on the gate region can help reduce gate leakage of the device.

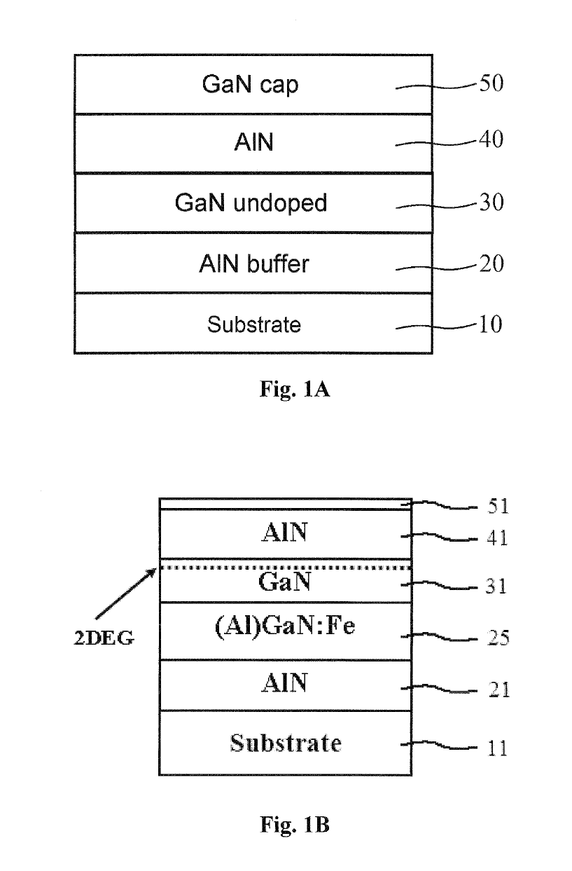

FIG. 1 A shows an AlN/GaN structure that can be used in fabricating an AlN/GaN HEMT in accordance with an embodiment of the present invention. The AlN/GaN stacked structure can be grown on a substrate such as c-plane sapphire, silicon, GaN, or SiC through Molecular Beam Epitaxy (MBE) or metal organic chemical vapor deposition (MOCVD) methods. The growth process can begin with surface nitridation of the substrate 10 at high temperatures using an RF nitrogen plasma source, followed by the growth of a thin AlN nucleation layer 20. Then, a low-defect GaN buffer 30 can be grown. In one embodiment, the GaN buffer 30 can have a thickness of 2-3 μm. Finally, the two dimensional electron gas channel layer can be formed by growing a thin (for example less than 50 nm thick, and in some cases less than 5 nm thick) AlN layer 40. The AlN layer 40 can be formed, for example, at 600-1100° C. An optional undoped GaN cap layer 50 can be included to protect the AlN layer 40.

FIG. 1B shows another AlN/GaN structure that can be used in fabricating an AlN/GaN HEMT in accordance with an embodiment of the present invention. According to an embodiment, the AlN/GaN structure can be grown on a substrate using RF plasma-assisted MBE. An AlN nucleation layer 21 can be grown on a nitrided c-plane sapphire, silicon, GaN, or SOI based poly SiC, 4H-SiC, or 6H-SiC wafer 11. The AlN nucleation layer 21 can be grown to a thickness of, for example, 20 nm. Next, Fe-doped GaN 25 can be grown on the AlN nucleation layer 21 under slightly N-rich conditions, followed by growth of undoped GaN under the slightly N-rich conditions. The Fe-doped GaN 25 and the undoped GaN formed under the slightly N-rich conditions can each be formed to a thickness of about 0.5 μm. Undoped GaN can then be grown under slightly Ga-rich conditions to complete the undoped GaN layer 31. The GaN layer grown under slightly Ga-rich conditions can be formed to have a thickness of about 1.5 μm. In one embodiment, the GaN layer can be grown under slightly Ga-rich conditions at about 730° C. Finally, a thin undoped AlN layer 41 can be formed on the GaN layer 31. The AlN layer 41 can be formed, for example, at 700° C. In one embodiment, the AlN layer 41 can be formed to a thickness of 3.5 nm. A thin (about 1 nm) undoped GaN layer 51 can be optionally provided as a protective cap layer.

From the AlN/GaN structures such as shown in FIGS. 1A and 1B, an E-mode AlN/GaN HEMT device can be fabricated.

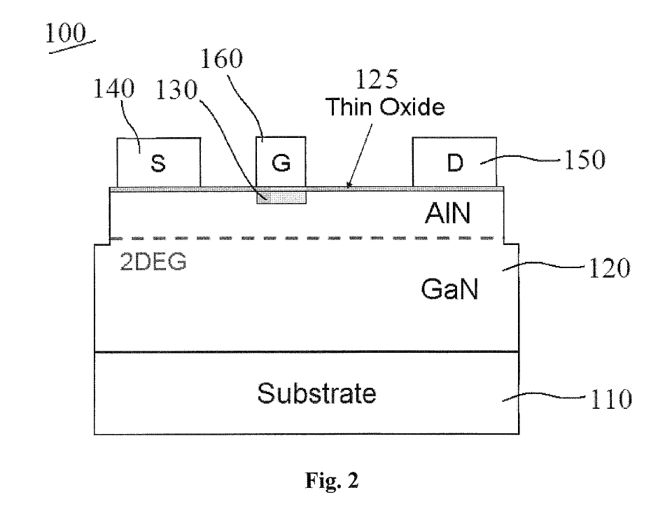

For example, referring to FIG. 2, an E-mode AlN/GaN HEMT 100 can include an AlN/GaN structure 120 on a substrate 110. In one embodiment, the AlN/GaN structure 120 can include the layers 20, 30, 40, and optionally 50 as shown in FIG. 1A. In another embodiment, the AlN/GaN structure 120 can include the layers 21, 25, 31, 41, and optionally 51 as shown in FIG. 1B. In certain embodiments where protective layers such as layer 50 or 51 are omitted, the AlN layer surface can be treated with an ultra violet (UV)-generated ozone to protect the AlN layer from photoresist development solution that may be used in device formation. For example, a thin oxide layer 125 can be formed on the AlN layer by the UV-ozone treatment.

For device formation, mesa etching can be performed and source and drain Ohmic contacts 140 and 150 can be formed. The gate area for the E-mode HEMT 100 can be defined using, for example, conventional photolithography processes or Poly(methyl methacrylate) (PMMA)-based electron beam direct writing lithography, and an aluminum oxide 130 can be formed on the gate area (below where the gate electrode is to be formed) through an oxygen plasma treatment in accordance with an embodiment of the present invention. The plasma treated region can be the region defined for the gate contact. According to one embodiment, the oxygen plasma treatment can further oxidize the AlN to reduce the AlN thickness below the gate contact region and adjust the threshold voltage. The gate electrode 160 can then be formed in the gate region on the oxide 130. The oxide can be Al₂O₃ formed by an O₂ plasma treatment. In alternate embodiments, at least one of N₂O, NO, N₂, He, Ar, Xe, Ne, and NH₃ may be used in place of, or in addition to, the O₂ plasma treatment, where their inclusion provides a similar effect as the O₂ plasma treatment. For example, the alternate plasma treatments may be able to positively shift the threshold voltage when performed for a particular duration.

For applications where D-mode and E-mode HEMTs are fabricated on a single chip, the photolithography or electron beam direct lithography process defining the gate area for the E-mode HEMT can cover the gate areas of the D-mode HEMTs. Then, once the oxygen plasma process is performed and the mask covering the gate regions for the D-mode HEMTs are removed, gate electrodes can be formed on both the E-mode and D-mode HEMTs.

Advantageously, for analog RF applications, by using the subject E-mode HEMT, a negative-polarity voltage supply can be eliminated because the E-mode HEMT does not require a negative-polarity voltage supply for operation, resulting in reduction to the circuit complexity and cost. In addition, for digital applications, the subject E-mode HEMT can be easily utilized in DCFL circuit configurations that feature integration of D-mode and E-mode HEMTs

Accordingly, examples of embodiments of the invention are provided below. These embodiments should not be construed as limiting.

1. A method for fabricating an enhancement mode HEMT, comprising: performing an O₂ plasma treatment on a gate area of the HEMT for a duration capable of increasing the threshold voltage of the HEMT before any gate metallization process. At least one of N₂O, NO, N₂, He, Ar, Xe, Ne, and NH₃ may be used alternatively or in addition to the O₂ plasma treatment.

2. Methods according to embodiment 1, wherein the duration is for a time greater than 6 s; wherein the duration is for a time greater than 12 s; wherein the duration is for a time greater than 18 s; wherein duration is about 18 s; wherein the duration is about 24 s; wherein the duration is a time between 18 s and 24 s.

3. A method according to embodiment 1, wherein the HEMT is an AlN/GaN HEMT.

4. A method according to embodiment 3, wherein fabricating the AlN/GaN HEMT comprises forming layers using RF plasma-assisted molecular beam epitaxy.

5. A method according to embodiment 3, wherein fabricating the AlN/GaN HEMT comprises forming layers using metal organic chemical vapor deposition.

6. Methods according to embodiments 4 or 5, wherein the AlN/GaN layers comprise: an AlN nucleation layer grown on a nitrided c-plane sapphire, silicon, GaN, or 6H-SiC wafer; an undoped GaN layer grown on the AlN nucleation layer; and a thin undoped AlN layer grown on the undoped GaN layer.

7. Methods according to embodiments 4 or 5, wherein the AlN/GaN layers comprise: an AlN nucleation layer grown on a nitrided c-plane sapphire, silicon, GaN, or 6H-SiC wafer; an Fe-doped GaN layer grown on the AlN nucleation layer under slightly N-rich conditions; undoped GaN grown on the Fe-doped GaN layer under the slightly N-rich conditions; undoped GaN grown under slightly Ga-rich conditions on the undoped GaN layer grown under the slightly N-rich conditions; and a thin undoped AlN layer grown on the undoped GaN layer.

8. A method according to embodiments 6 or 7, further comprising a capping layer formed on the AlN layer before performing etching processes to form source and drain Ohmic contacts. The capping layer can be a thin undoped GaN layer.

9. A method according to embodiments 6 or 7, further comprising UV-ozone treating the thin undoped AlN layer before performing etching processes to form source and drain Ohmic contacts.

10. Methods according to embodiment 1, wherein a second gate area for a second HEMT on a same substrate as the HEMT is covered during the performing of the O₂ plasma treatment on the gate area of the HEMT for the duration, whereby the HEMT functions as the enhancement mode HEMT and the second HEMT functions as a depletion mode HEMT.

11. An E-mode HEMT for analog and digital applications, comprising: an AlN/GaN HEMT having an Al₂O₃ dielectric formed through an O₂ plasma treatment directly on an AlN layer of the AlN/GaN HEMT at a gate area of the AlN/GaN HEMT.

12. The E-mode HEMT according to embodiment 11, wherein the AlN/GaN HEMT is formed on a sapphire, silicon, GaN, poly SiC, or SiC substrate.

13. A power amplifier comprising: an E-mode AlN/GaN HEMT having an Al₂O₃ dielectric formed through an O₂ plasma treatment directly on an AlN layer of the AlN/GaN HEMT at a gate area of the AlN/GaN HEMT.

14. A Direct-coupled FET logic comprising an E-mode AlN/GaN HEMT integrated with a D-mode AlN/GaN HEMT, the E-mode AlN/GaN HEMT having an Al₂O₃ dielectric formed through an O₂ plasma treatment directly on an AlN layer of the E-mode AlN/GaN HEMT at a gate area of the E-mode AlN/GaN HEMT.

Following are examples that illustrate procedures for practicing and understanding the invention. These examples should not be construed as limiting.

### EXAMPLE 1

A structure as shown in FIG. 1A was fabricated by growing the AlN and GaN layers on c-plane sapphire with a MBE system equipped with a SVT Associates RF nitrogen plasma source (SVTA-RF45). During growth, reflection high-energy electron diffraction (RHEED) was used to monitor surface morphology. Other in-situ measurements, including emissivity-corrected surface temperature, thin film growth rate, and II/V flux ration were performed by a combination of pyrometry and a two-color reflectometery (SVTA-IS4000). A surface nitridation of the sapphire substrate (10 of FIG. 1A) was performed at high temperatures using the RF nitrogen plasma source, followed by the growth of the thin AlN nucleation layer (20 of FIG. 1A). The GaN buffer (30 of FIG. 1A) was grown to a thickness of about 2 μm. Finally the AN layer (40 of FIG. 1A) was grown to a thickness of about 5-50 nm at 700° C. Some of the samples included the undoped GaN cap layer (50 of FIG. 1A) grown to a thickness of about 1 nm. According to the test measurements, the mobility and sheet carrier density in the two-dimensional electron gas channel ranged from 1300-1900 cm²/V·s and 1.5−3.5×10¹³ cm⁻², respectively. In addition, the typical sheet resistance of the samples was below 200 Ω/square.

Because conventional positive resist developer solution is known to attack the AlN layer, for samples omitting the cap layer (50 of FIG. 1A), the AlN layer surface was treated with a UV-generated ozone prior to the normal device fabrication to form a thin oxide 125.

Device fabrication began with mesa isolation by Cl₂/Ar inductively coupled plasma (ICP) etching (150W source power, 40 W RF chuck power). Isolation currents were less than 2 μA at 40 V bias for a mesa depth of 1200 Å. Ohmic contacts (see reference 140 and 150 of FIG. 2) were formed by lift-off of e-beam deposited Ti/Al/Ni/Au based metallization, and subsequently annealed at 850° C. for 30 s under a N₂ ambient. A sheet resistance of ˜167 ohm/sq was achieved using Ti/Al based Ohmic contacts annealed at 850° C. for 30 s. The gate fingers with a dimension of 400 nm×200 μm were defined using a Raith electron beam direct write system, followed with an e-beam metal deposition of Ti/Au as the gate metallization. The distance between source and drain was 2 μm. The DC characteristics of the HEMTs were measured with a Tektronix curve tracer 370A and an HP 4156 parameter analyzer.

By oxidizing the AlN into Al oxides, the AlN layer thickness of the AlN/GaN HEMT can be decreased and the threshold voltage can be shifted to more positive voltages. The Al oxides can be created by oxidizing the AlN layer with an oxygen plasma using either a barrel etcher or parallel plate etching with a small RF power range, such as from 20-40 W. In these examples, in order not to increase source and drain parasitic resistance, the oxygen plasma treatment was only performed on the gate area after photolithographic gate definition. With this approach, D-mode and E-mode HEMTs were fabricated on the same wafer and the E-mode HEMTs were formed by exposing their gate areas to the oxygen plasma for up to 24 s.

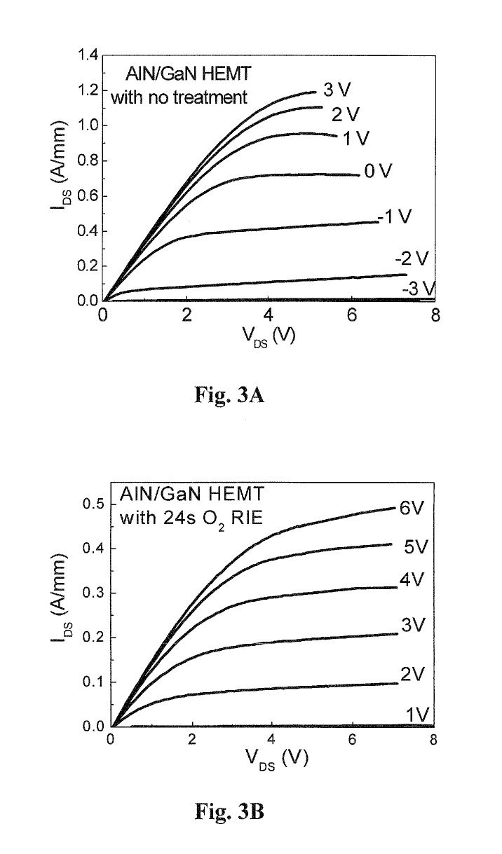

The drain current characteristics of a D-mode and an E-mode AlN/GaN HEMT that were fabricated side-by-side on the same wafer are illustrated in FIGS. 3A and 3B. Referring to FIG. 3A, which illustrates a D-mode device (defined by not having an oxygen plasma treatment performed thereon), the maximum saturation current and the threshold voltage were 1.25 A/mm (at a gate bias voltage of 3 V) and −2.8 V, respectively. Referring to FIG. 3B, for the E-mode AlN/GaN HEMT (where the gate area was exposed to the oxygen plasma for 24 s), the maximum saturation current and the threshold voltage were 0.45 A/mm (at a gate bias voltage of 6 V) and −1V, respectively.

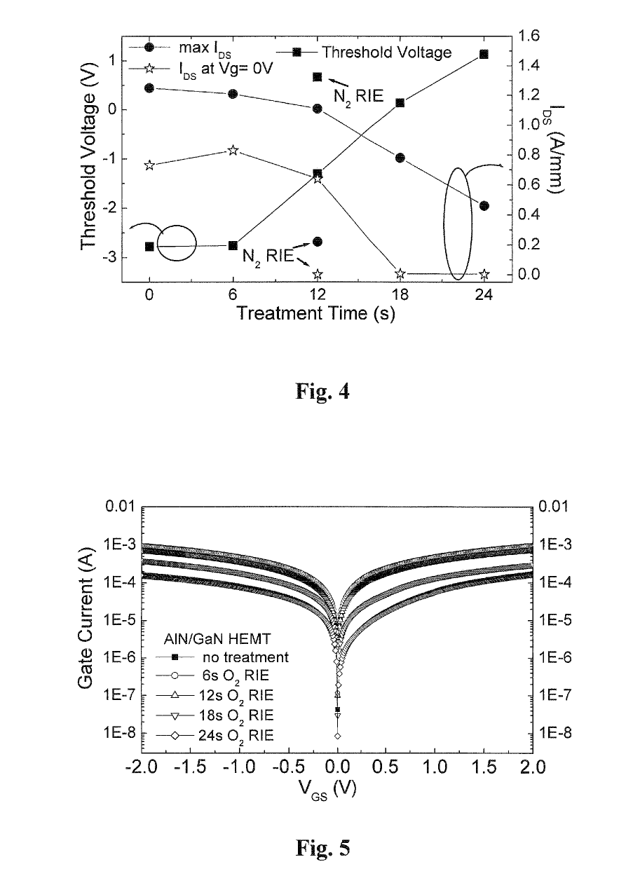

As illustrated in FIG. 4, the threshold voltage of the AlN/GaN HEMT could be easily controlled by adjusting the oxygen plasma exposure time. FIG. 4 shows the threshold voltage (left hand y-axis and line with boxes), the drain current at zero gate bias voltage (right hand y-axis and line with stars), and the maximum drain current (right hand y-axis and line with circles) as a function of plasma exposure time. Referring to FIG. 4, it took around 3 s to get the plasma stabilized and it can be seen that there was no observable threshold voltage shift for 6 s of oxygen plasma. After 6 s, the threshold voltage increased almost linearly proportional to the oxygen plasma exposure time. In this example implementation, the threshold voltage of the HEMT was shifted from −3.2 V to 1V in accordance with the oxygen plasma exposure time. The top portion of the AN layer was converted into an Al oxide layer during the oxygen plasma treatment. From the 6 s point, the drain current at zero gate bias voltage decreased as the oxygen plasma exposure time increased. Then, as the plasma exposure time reached 18 s, the drain current at floating gate bias became zero and the AlN/GaN HEMT converted into E-mode operation. A similar trend occurred for the maximum drain current, defined as the drain current modulation starting to be clamped, which is shown as also decreasing gradually as the oxygen plasma exposure time increased. As mentioned previously, the wafer was exposed to ozone for 1 min prior to the HEMT fabrication to oxidize the AlN surface layer for protecting the AN during the fabrication. In order to confirm that this ozone treatment would not damage the HEMT performance, an AlN/GaN HEMT was treated with 1 min of UV generated ozone at the gate area prior to the gate metal deposition; there was no drain current change or threshold voltage shift observed by the UV generated ozone treatment. FIG. 4 also includes single points (as labeled) of threshold voltage, drain current at zero gate bias voltage, and maximum drain current for N₂ plasma exposure at a 12 s treatment time. As shown by the labeled points, nitrogen can shift the threshold voltage of the device, but not as effectively as oxygen. While the oxygen treatment can oxidize the AlN to aluminum oxide (also reducing the thickness of the AlN layer), nitrogen (and other plasma treatments) can only create damage to the two-dimensional gas (2DEG) channel.

FIG. 5 shows the forward and reverse gate current of the AlN/GaN HEMTs treated with different oxygen plasma exposure time. There was no forward Schottky turn-on observed. Instead, a metal oxide semiconductor (MOS) diode-like I-V characteristic was obtained. The longer the plasma treatment applied to the gate area of the AlN/GaN HEMT, the lower the current that was achieved. This result indicates a thicker Al oxide layer formed in the gate area.

As demonstrated by this example, a simple oxidation treatment procedure was able to positively shift the threshold voltage of AlN/GaN HEMTs to provide E-mode HEMTs. In addition, the oxygen plasma converted the AlN to Al oxide and reduced gate current. According to embodiment of the present invention, the subject oxidation treatment can be used to fabricate both E- and D-mode AlN/GaN HEMTs on the same wafer.

### EXAMPLE 2

A structure as shown in FIG. 1B was fabricated by growing the AlN and GaN layers by RF plasma-assisted MBE. A 20 nm AlN nucleation layer (21 of FIG. 1B) was deposited on a nitrided c-plane sapphire or 6H-SiC wafer (11 of FIG. 1B). Next, about 0.5 μm of Fe-doped GaN (25 of FIG. 1B) was grown under slightly N-rich conditions, followed by another 0.5 μm GaN buffer under the same conditions but without Fe doping. Then, 1.5 μm of undoped GaN was grown under slightly Ga-rich conditions at about 730° C. The combined undoped GaN layers can constitute the GaN layer 31 of FIG. 1B. A relatively low threading dislocation density (˜1×108 cm⁻²) in these films was confirmed by etch pit density measurements, using atomic force microscopy (AFM), and by transmission electron microscopy (TEM). Finally a 3.5 nm undoped AlN barrier (41 of FIG. 1B) was grown on top of the GaN layer (31 of FIG. 1B) at about 700° C., followed in certain samples by 1 nm of undoped GaN as a protective cap layer (51 of FIG. 1B). The AlN barrier layer 41 is grown to a thickness of less than 4 nm to inhibit thin film cracking.

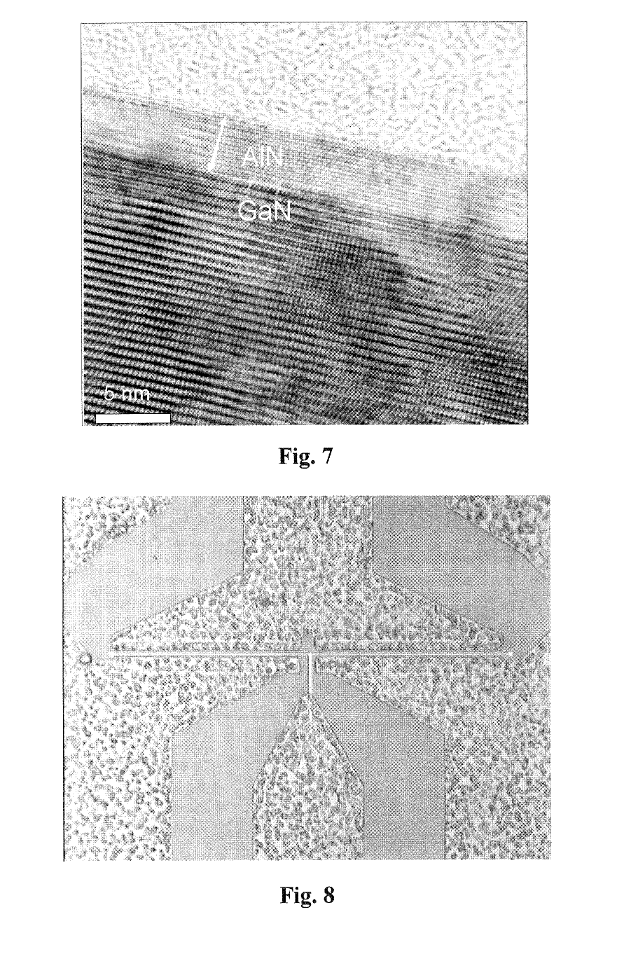

Uniform and scalable growth of high-quality devices over large diameters, enabling high-yield production, can be accomplished by using the MBE growth process. FIG. 7 shows a cross-sectional TEM picture of the top AlN/GaN layers (e.g. GaN layer 31 and AlN layer 41) illustrating an excellent abrupt interface between the AlN and GaN. The AlN is below the critical thickness so as not to induce additional threading dislocations in the structure. This can be important for achieving high electron mobility in the 2DEG. The low defect densities obtained in relatively thin layers indicate that high-quality AlN/GaN HEMTs can be grown with low wafer bowing and less possibility of thin film cracking on large diameter substrates.

To maintain optimized conditions during MBE growth, surface morphology was monitored in-situ by RHEED while emissivity-corrected surface temperature, thin-film growth rate, and III/V flux ratio were measured by a combination of pyrometry and two-color reflectometry (SVTA-IS4000). The optical and electrical properties of the samples were characterized by cathodoluminescence, Hall, and capacitance-voltage measurements. Non-destructive Hall measurements on the as-grown wafer showed a room temperature 2DEG mobility of about 1570 cm²/V·s at a sheet density of about 2×10¹³ cm⁻².

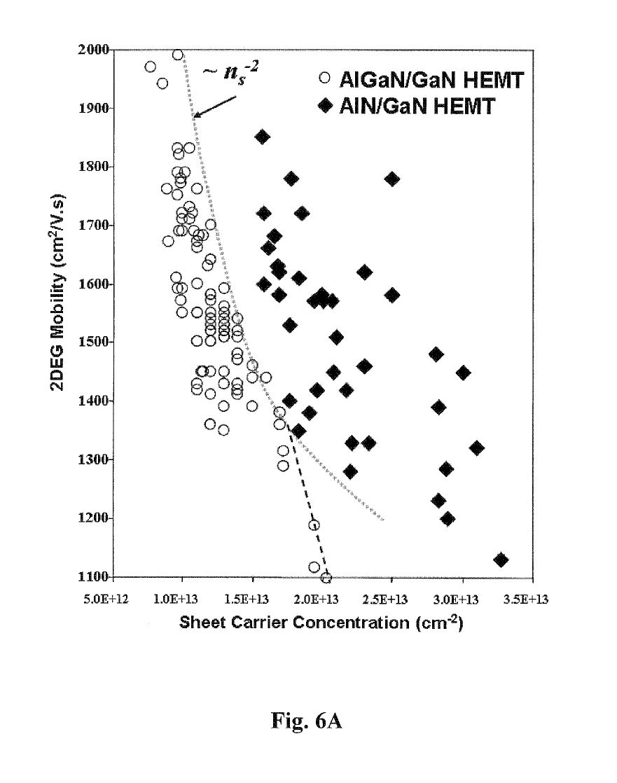

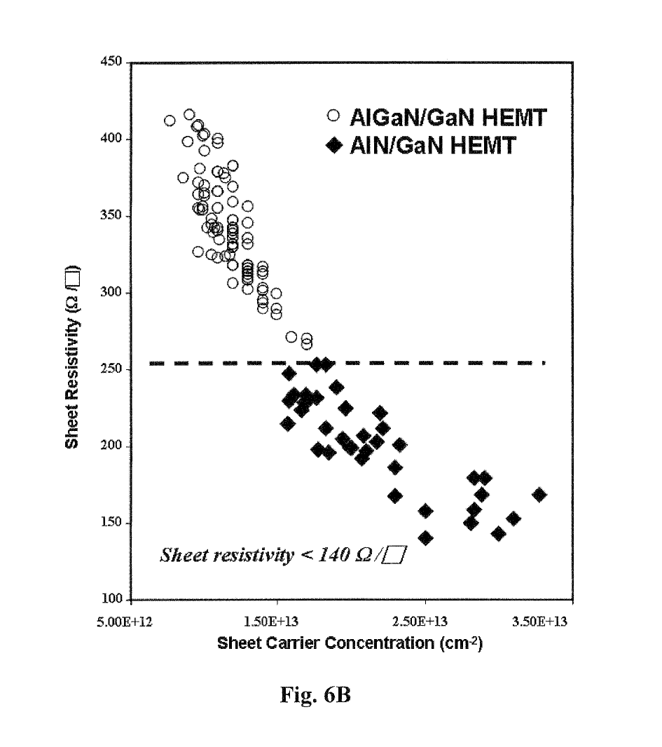

FIG. 6A shows room temperature mobility versus sheet carrier concentration of the 2DEG interface in both AlGaN/GaN and AlN/GaN HEMTs; and FIG. 6B shows the sheet resistivity versus sheet carrier concentration in both AlGaN/GaN and AlN/GaN HEMTs. The product of both high sheet carrier concentration and mobility in these AlN/GaN HEMTs resulted in a minimum sheet resistivity, ρ_{sheet˜}140 Ω/square, as shown in FIG. 6B.

Once the AlN/GaN structures, such as shown in FIG. 1B, were fabricated, to protect the device surface layer, the samples were treated by either an O₂ plasma treatment or by UV ozone for periods of 6 s-60 s. The two treatments were compared for their ability to create an E-mode HEMT. The treatments were performed to create an Al₂O₃ gate dielectric. The O₂ plasma exposure was carried out at a pressure of 10 mTorr and power density of 20 W. Device fabrication began with mesa isolation by Cl₂ /Ar ICP etching (150 W source power, 40 W RE chuck power). Isolation currents were in the low μA at 40 V bias for a mesa depth of 1200Å. Ohmic contacts (see reference 140 and 150 of FIG. 2) were formed by lift-off of e-beam deposited Ti/Al/Ni/Au based metallization, and subsequently annealed at 850° C. for 30 s under a N₂ ambient. A sheet resistance of ˜167 ohm/sq was measured using a transmission line method (TLM). Finally, the submicron gate fingers with the dimensions of 380 nm×200 μm were defined by e-beam-lithography, followed by e-beam metal deposition of Ti/Au as the gate contact. The distance between source and drain is 2 μm. A plan view SEM image of the fabricated device is shown in FIG. 8.

As mentioned previously, AlN can easily be attacked by photoresist develop solution, BOE, and HF, so that a protective layer is needed during the device fabrication. Silicon nitride (SiN) has widely been used for this purpose. In the related art, plasma enhanced vapor deposition or electron beam deposition was used to deposit the SiN. Since the HF and BOE would attack the SiN, after the Ohmic contact pattern definition, the SiN cannot be removed by the HF solution or BOE. In addition because CF₄ plasma exposure may have a passivation effect on the 2DEG of the AlGaN/GaN HEMT, the CF₄ plasma cannot be used to remove the SiN prior to the Ohmic metal deposition. Therefore, in the related art. the Ohmic metal was directly deposited on the protective SiN and the metal was alloyed through the SiN.

According to the invention, simple O₂ plasma treatment, and for comparison an UV-Ozone (O₃) treatment, was employed to convert the AlN to Al₂O₃, creating both a gate dielectric and avoiding issues of the stability of AlN. The O₂ plasma treatment can be carried out as a rapid ion etch (RIE). The DC characteristics of the HEMTs were measured with a Tektronix curve tracer 370A and an HP 4156 parameter analyzer. The RF performance of the HEMTs was characterized with an HP 8723C network analyzer.

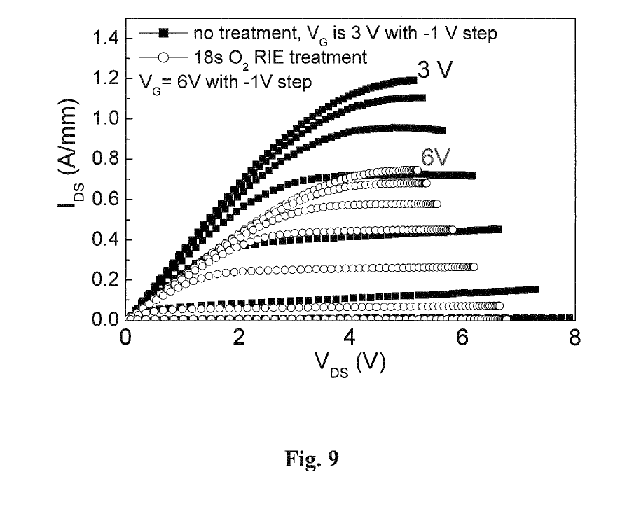

As shown in FIG. 9, a maximum drain current density of 1.2 A/mm was measured at a gate bias voltage (V_{DS}) of about +4V for the 200-μm-gate-width device having no treatment thereon. As indicated by the Figure, the I-V characteristics are provided for V_{G} beginning at 3 V (see top curve) and stepping down by −1 V. The device pinch-off voltage (V_{G}) was −4 V. The current density and threshold voltage could be controlled via the O₂ plasma exposure time. For example, as shown in FIG. 9, the I_{DS}-V_{DS} characteristics after an 18 s O₂ plasma treatment are provided, highlighting the change in both parameters. The I-V characteristics are provided for V_{G} beginning at 6 V (see top curve indicated by circles) and stepping down by −1 V. The gate forward and reverse currents were unaffected for O₂ plasma exposure times up to ˜12 s (not shown in the Figure) and both decreased by an order of magnitude for longer times. The gate currents were several orders of magnitude lower than the drain current over a wide swing of gate-source voltages.

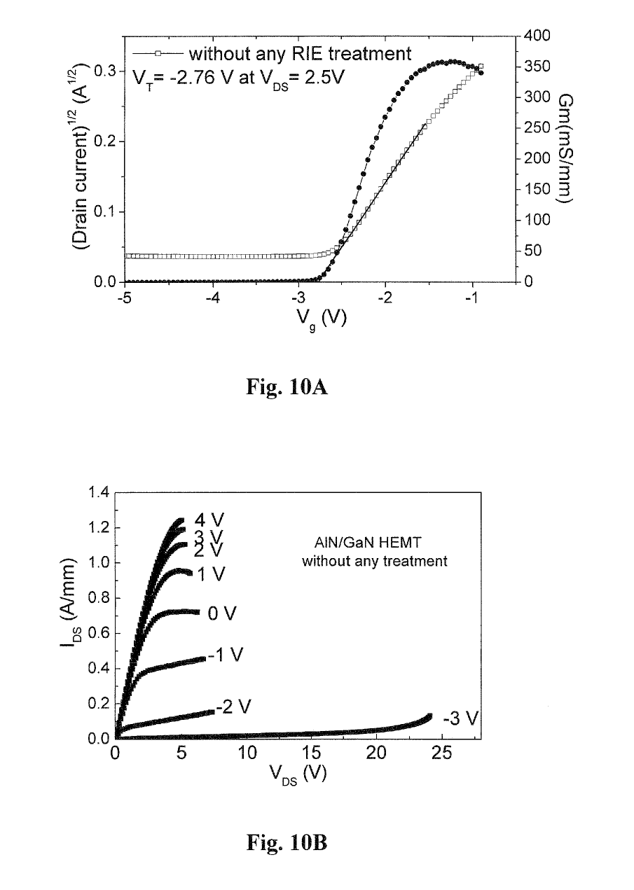

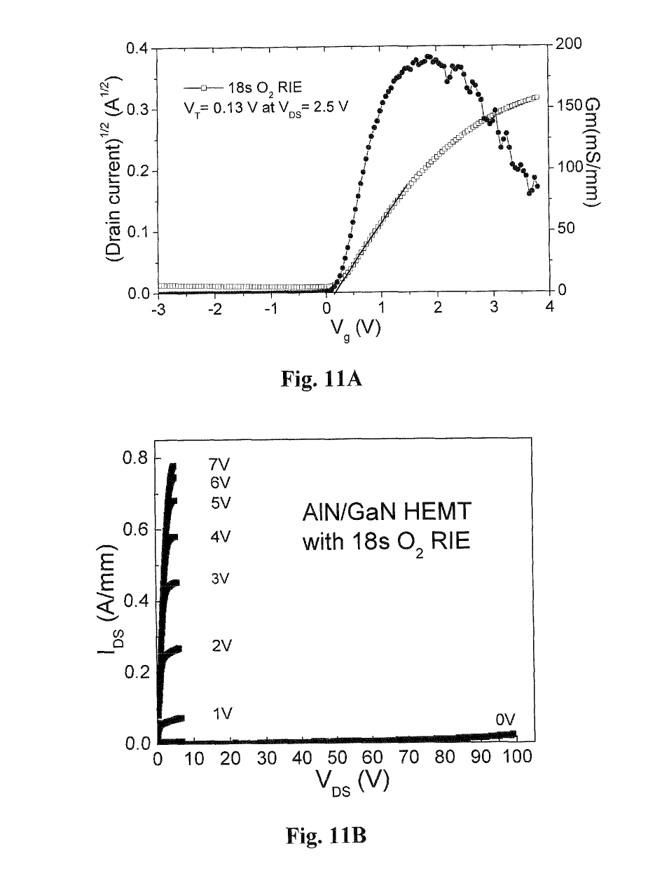

The corresponding transfer characteristic of these devices is shown in FIGS. 10A-10B for the untreated HEMTs and 11A-11B for HEMTs exposed to the O₂ plasma for 18 s. As shown in FIGS. 10A and 10B, for the untreated HEMTs, a maximum transconductance of 330 mS/mm was obtained (see line with circles) with a breakdown voltage of 24 V and a threshold voltage of −2.76V. Accordingly, the untreated HEMT is in depletion-mode operation. Though not shown in the plots, similar numbers were achieved after a 6 s O₂ plasma exposure. However, but for a 12 s O₂ plasma exposure, the breakdown voltage increased to 35 V, with a lower threshold of −1.31V and a maximum gₘ of 305 mS/mm. As shown in FIGS. 11A and 11B, an 18 s O₂ plasma exposure produced a breakdown voltage of 100 V, with a positive threshold voltage (E-mode operation) of 0.13V and a maximum gₘ of 191 mS/mm. Though not shown in the plots, for a 24 s O₂ plasma exposure, the breakdown voltage degraded to 47V and maximum gₘ to 142 mS/mm, with a threshold voltage of 1.13V. As a control experiment, samples were exposed to N₂ plasmas under similar conditions, simulating the ion bombardment effect without the reactive oxygen. For a 12 s N, plasma exposure, the gₘ dropped to 121 mS/mm and the maximum drain current density to 0.2 A/mm with a threshold voltage of 0.66 V. Similarly, UV-ozone exposure failed to produce E-mode operation, with the threshold voltage remaining significantly negative for all exposure times.

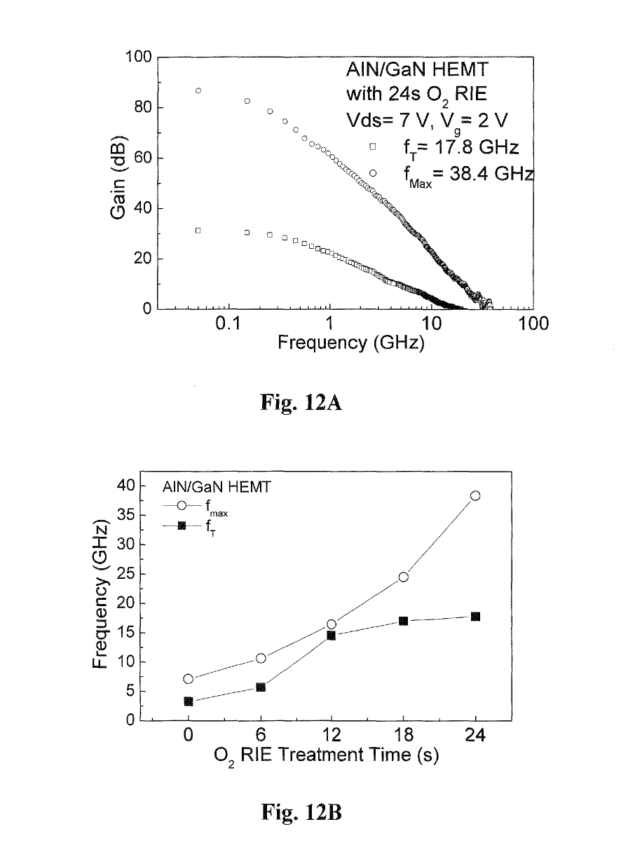

An example of the small signal RF performance of the O₂ plasma exposed AlN/GaN HEMTs is shown in FIG. 12A. The device exposed for 24 s was biased at V_{ds}=7V and V_{g}=+2V during the measurements. A unity current gain cutoff frequency, ƒ_{T}, and power gain cutoff frequency, ƒₘₐₓ, of 17.8 and 38.4 GHz were obtained, respectively. The dependence of RF performance on O₂ plasma exposure time is shown at FIG. 12B. The ƒ_{T} values increase because the small decreases in gₘ are more than offset by the decrease in gate-drain and gate-source capacitance. The larger improvements in ƒₘₐₓ are due to the lower gate capacitance when the AlN is oxidized.

In summary, untreated HEMTs exhibited a breakdown voltage of 24V, drain current density of 1.2 A/mm at gate voltage of +4 V and excellent pinch-off characteristics at gate voltage of −4 V. E-mode devices showed a maximum breakdown voltage of 100V, drain-source current density of 0.45 A/mm and threshold voltage of +1.1 V. The current gain cut-off frequency, ƒ_{T}, and maximum frequency of oscillation, ƒₘₐₓ, were 17.8 GHz and 38.4 GHz, respectively for 0.4×100 μm² gate E-mode HEMTs.

Accordingly, AlN/GaN HEMTs with a thin aluminum oxide gate barrier using oxidation treatments have been demonstrated. As shown by these examples, the threshold voltage can be tuned from negative to positive based on oxygen plasma exposure time. An O₂ plasma treatment was used to oxidize the AlN surface layer and this layer served as the gate oxide layer and a protective layer during the device fabrication. By controlling the duration of this oxidation treatment, the device characteristics can be tuned to achieve both E-and D-mode operation. Furthermore, N₂ plasma and UV-ozone treatments for comparable periods did not lead to E-mode operation.

In addition, these devices show promising dc and RF performance. Accordingly, embodiments of the present invention can be used to enhance the performance of GaN-based power amplifiers.

For the above examples, a plasma based recess gate etching using ICP system was used to fabricate the E-mode AIGaN/GaN HEMT. The ICP etching may create ion bombardment damage. Accordingly, after the gate recess etching, a thermal annealing step was performed to remove the plasma damage in order to make the HEMTs functional. However, the thermal annealing may degrade the gate contacts. Therefore, additional care can be taken to address gate contact issues. However, since annealing issues are not the subject of the present disclosure, methods and mechanisms to improve gate contact issues due to the annealing will not be discussed herein.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

What is claimed is:

1. An enhancement mode (E-mode) high electron mobility transistor (HEMT) for analog and digital applications, comprising:
a first semiconductor layer on a substrate;
a second semiconductor layer on the first semiconductor layer, the first semiconductor layer and the second semiconductor layer being of materials capable of forming a two dimensional electron gas channel therebetween;
a gate dielectric on the second semiconductor layer; and
a gate electrode on the gate dielectric, wherein the gate electrode is disposed over a first portion of the second semiconductor layer,
wherein the first portion of the second semiconductor layer has a first thickness and a second portion of the second semiconductor layer adjacent the first portion has a second thickness that is thicker than the first thickness.

2. The E-mode HEMT according to claim 1, wherein the first semiconductor layer is a GaN layer and the second semiconductor layer is an AlN layer.

3. The E-mode HEMT according to claim 2, wherein the gate dielectric comprises Al₂O₃ formed through an O₂ plasma treatment directly on the AlN layer.

4. The E-mode HEMT according to claim 1, wherein the substrate comprises sapphire, silicon, GaN, poly SiC, or SiC.

5. The E-mode HEMT according to claim 1, wherein a portion of the gate dielectric is disposed below a top surface of the second portion of the second semiconductor layer.

6. A power amplifier comprising the E-mode HEMT of claim 1.

7. A Direct-coupled FET logic comprising the E-mode HEMT of claim 1 integrated with a depletion mode (D-mode) HEMT on the substrate.

8. A method for fabricating an enhancement mode (E-mode) high electron mobility transistor (HEMT), the method comprising:
providing a substrate comprising a two dimensional electron gas channel layer, the two dimensional electron gas channel layer formed by a second semiconductor layer on a first semiconductor layer on the substrate;
forming source and drain contacts on the second semiconductor layer;
performing a plasma treatment to a surface of the second semiconductor layer; and
performing a gate metallization process, the gate metallization process forming a gate electrode on the plasma treated surface of the second semiconductor layer.

9. The method according to claim 8, wherein the plasma treatment is performed for a duration capable of positively shifting a threshold voltage of the HEMT.

10. The method according to claim 9, wherein the duration is for a time in a range of 6 s to 30 s.

11. The method according to claim 9, wherein the duration is a time in a range of 18 s to 24 s.

12. The method according to claim 8, wherein the plasma treatment comprises an O₂ plasma treatment.

13. The method according to claim 12, wherein the plasma treatment further comprises using at least one of N₂O, NO, N₂, He, Ar, Xe, Ne, and NH₃.

14. The method according to claim 8, wherein the plasma treatment comprises using at least one of N₂O, NO, N₂, He, Ar, Xe, Ne, and NH₃.

15. The method according to claim 8 wherein the substrate comprises a nitrided c-plane sapphire, silicon, GaN, or 6H-SiC wafer.

16. The method according to claim 8, wherein providing the substrate comprising the two dimensional electron gas channel layer comprises:
forming an AlN nucleation layer on the substrate;
forming an undoped GaN layer on the AlN nucleation layer, the undoped GaN layer providing the first semiconductor layer;
forming an undoped AlN layer on the undoped GaN layer, the undoped AlN layer providing the second semiconductor layer.

17. The method according to claim 8, wherein providing the substrate comprising the two dimensional electron gas channel layer comprises:
forming an AlN nucleation layer on the substrate;
forming an Fe-doped GaN layer on the AlN nucleation under slightly N-rich conditions;
forming a first undoped GaN layer on the Fe-doped GaN layer using the slightly N-rich conditions;
forming a second undoped GaN layer on the first undoped GaN layer using slightly Ga-rich conditions, wherein the first undoped GaN layer and the second undoped GaN layer provide the first semiconductor layer;
forming an undoped AlN layer on the second undoped GaN layer, the undoped AlN layer providing the second semiconductor layer.

18. The method according to claim 8, further comprising:
forming a capping layer on the second semiconductor layer before forming the source and drain contacts.

19. The method according to claim 8, further comprising performing a UV-ozone treatment to the surface of the second semiconductor layer before forming the source and drain contacts.

20. The method according to claim 8, further comprising:
covering a gate area for a second HEMT on the substrate during the performing of the plasma treatment to the surface of the second semiconductor layer, wherein the gate metallization process forms a second gate electrode on the gate area for the second HEMT, whereby the second HEMT functions as a depletion mode HEMT.
